(19) United States
(12) Patent Application Publication
(10) Pub. No.: US 2008/0230906 A1
(43) Pub. Date: Sep. 25, 2008

(54) CONTACT STRUCTURE HAVING DIELECTRIC SPACER AND METHOD

(76) Inventors: Keith Kwong Hon Wong, Wappingers Falls, NY (US); Chih-Chao Yang, Glenmont, NY (US); Haining S. Yang, Wappingers Falls, NY (US)

Correspondence Address: HOFFMAN WARNICK LLC, 75 STATE ST, 14TH FL, ALBANY, NY, 12207, US

(21) Appl. No.: 11/689,723

(22) Filed: Mar. 22, 2007

(51) Int. Cl. H01L 23/52; H01L 21/44

(52) U.S. Cl. 257/751; 438/643; 257/E23.141; 257/E21.476

(57) ABSTRACT

A contact structure and method of forming same are disclosed. The contact structure may include a metal body surrounded by a dielectric spacer, the metal body and the dielectric spacer positioned within an interlevel dielectric layer, wherein the metal body is electrically coupled to a silicide region below a lowermost portion of the metal body.

### BACKGROUND

1. Technical Field

The disclosure relates generally to integrated circuit (IC) fabrication, and more particularly, to a contact structure having a dielectric spacer and a method of forming same.

2. Background Art

In the integrated circuit (IC) fabrication industry, the continued miniaturization of devices presents a number of challenges relative to forming certain structures. One structure that presents a challenge is a contact structure that couples wiring and other devices. More particularly, as shown in FIG. 1, current interlevel dielectric (ILD) layers 8 may include silicon oxide 10 and silicon nitride 12, which make it difficult to pattern contact openings 14 for next generation technology. For example, current ILD layers 8 present problems with creating contact openings 14 at increasingly smaller critical dimensions (CD), having a straight profile, that do not undercut a silicide region 22 therebelow, and do not have residue at the bottom of contact opening 14. One particular challenge for a silicon oxide/silicon nitride dielectric scheme is addressing re-entry of ILD layer 8 into contact opening 14 caused by the smallness of the contact opening. When re-entry occurs, it causes formation of a throat portion 16 near a top of contact opening 14. Throat portion 16, as shown in FIG. 2, prevents filling during metal deposition to form a contact structure. As a result, the metal either does not enter contact opening 14 or a void 20 is present in the metal. Void 20 causes an increase in the contact resistance at the point where the contact meets silicide region 22, and may trap chemicals in subsequent processing such as chemical mechanical planarization (CMP).

### SUMMARY

A contact structure and method of forming same are disclosed. The contact structure may include a metal body surrounded by a dielectric spacer, the metal body and the dielectric spacer positioned within an interlevel dielectric layer, wherein the metal body is electrically coupled to a silicide region below a lowermost portion of the metal body.

A first aspect of the disclosure provides a contact structure comprising: a metal body surrounded by a dielectric spacer, the metal body and the dielectric spacer positioned within an interlevel dielectric layer, wherein the metal body is electrically coupled to a silicide region below a lowermost portion of the metal body.

A second aspect of the disclosure provides a method comprising: providing an interlevel dielectric layer having a contact opening therein, the contact opening exposing a silicide region at a lower portion of the contact opening; forming a dielectric spacer within the contact opening; performing an anisotropic reactive ion etch to remove the dielectric spacer at the lower portion of the contact opening and expose the silicide region; and filling the contact opening with a metal.

The illustrative aspects of the present disclosure are designed to solve the problems herein described and/or other problems not discussed.

### BRIEF DESCRIPTION OF THE DRAWINGS

These and other features of this disclosure will be more readily understood from the following detailed description of the various aspects of the disclosure taken in conjunction with the accompanying drawings that depict various embodiments of the disclosure, in which:

FIGS. 1-2 show conventional problems with contact structures.

FIGS. 3-5 show embodiments of a method forming a contact structure according to the disclosure, with FIG. 5 showing embodiments of a contact structure according to the disclosure.

FIG. 6 shows an alternative embodiment of the method of FIGS. 3-5 and an alternative embodiment of a contact structure.

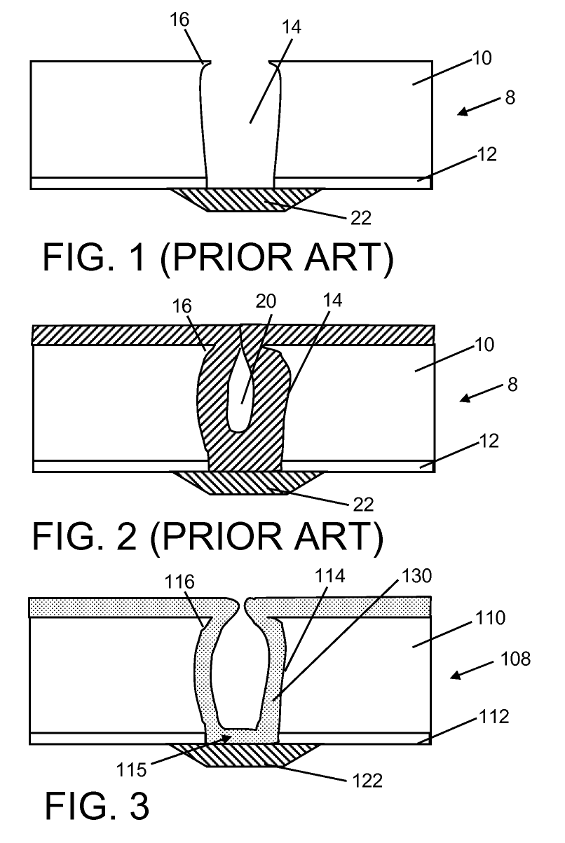

It is noted that the drawings of the disclosure are not to scale. The drawings are intended to depict only typical aspects of the disclosure, and therefore should not be considered as limiting the scope of the disclosure. In the drawings, like numbering represents like elements between the drawings.

### DETAILED DESCRIPTION

FIGS. 3-5 show embodiments of a method of forming a contact structure according to the disclosure, and FIGS. 5 and 6 show embodiments of contact structure 100, 200, respectively. FIG. 3 shows providing an interlevel dielectric (ILD) layer 108 having a contact opening 114 therein. In one embodiment, ILD layer 108 may include a silicon oxide layer 110 and a silicon nitride layer 112. However, the disclosure is not limited to only that type of ILD layer 108. In one embodiment, silicon nitride layer 112 may constitute an intrinsically stressed liner below ILD layer 108. Contact opening 114 exposes a silicide region 122 at a lower portion 115 of contact opening 114. As understood, silicide region 122 may be part of a transistor device (not shown). Contact opening 114 may be formed using any now known or later developed technique. For example, deposition of ILD layer 108, photolithography to pattern and etch a photoresist layer and etching to form contact opening 114. As indicated, contact opening 114 may include a throat portion 116 in ILD layer 108 near an upper part of ILD layer 108. ILD layer 108 may be formed above any other type of IC layer, e.g., another back-end-of-line (BEOL) layer of a device. In any event, the layer below ILD layer 108 includes a silicide region 122 to which contact structure 100, 200 (FIGS. 5, 6) is to electrically couple.

FIG. 3 also shows forming a dielectric spacer 130 within contact opening 114. In one embodiment, this process includes depositing a dielectric, e.g., silicon oxide, silicon nitride, etc., such that it coats an interior of contact opening 114 including silicide region 122. In one embodiment, dielectric spacer 130 includes a dielectric material having a dielectric constant less than approximately 2.9, i.e., a low-k dielectric such as hydrogenated silicon oxycarbide (SiCOH), porous SICOH, silsequioxanes, and spin on dielectric such as SiLK. Dielectric spacer 130 substantially fills, i.e., makes it much smaller but does not fully close, throat portion 116 of contact opening 114 in ILD layer 108 near an upper part of ILD layer 108.

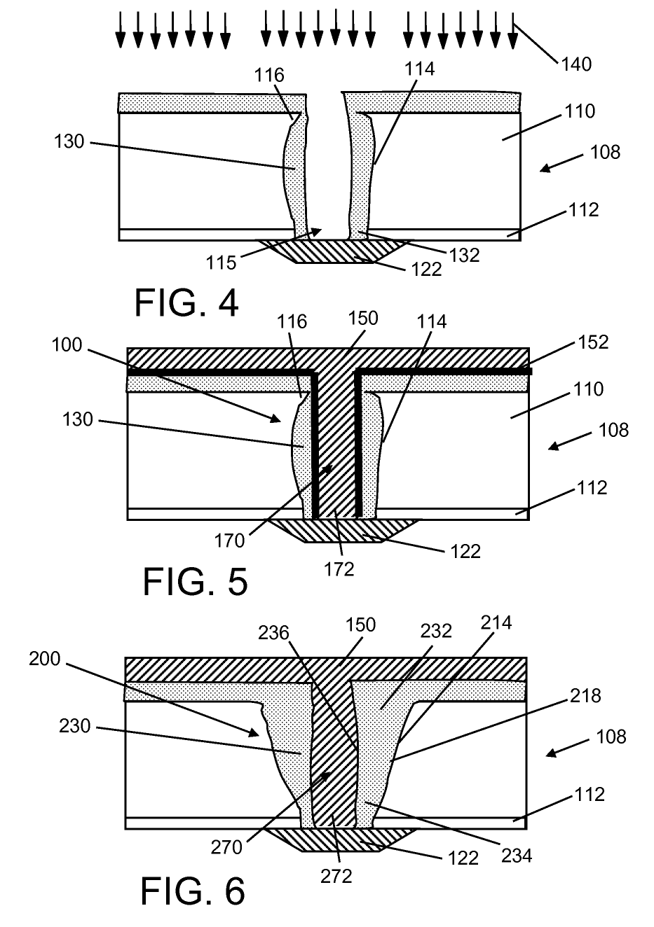

FIG. 4 shows performing an anisotropic reactive ion etch (RIE) 140 to remove dielectric spacer 130 at lower portion 115 of contact opening 114 and expose silicide region 122. In one embodiment, dielectric spacer 130 is removed at lower portion 115, but sidewalls 132 of dielectric spacer 130 remain in contact with silicide region 122. FIG. 5 shows filling contact opening 114 with a metal 150 to form a metal body 170 of a contact structure 100. Metal 150 may include any now known or later developed metal material for forming a contact structure, e.g., copper (Cu), aluminum (Al), tungsten (W), etc. As understood, an appropriate diffusion barrier liner 152, e.g., of tantalum (Ta), titanium, (Ti), tantalum nitride (TaN), titanium nitride (TiN), other refractory metals or mixtures thereof, may also be employed. In some cases, liner 152 may be omitted.

Turning to FIG. 6, in an alternative embodiment, an argon sputtering may be performed after ILD layer 108 and contact opening 214 formation such that an outer surface 218 of contact opening 214 is substantially frusto-conical. In this case, a dielectric spacer 230 forming includes non-conformally depositing a dielectric such that an upper portion 232 of dielectric spacer 230 is thicker than a lower portion 234 of dielectric spacer 230. The anisotropic etch of FIG. 4 creates a substantially straight wall 236 in contact opening 214 through dielectric spacer 230. Filling of contact opening 214 (shown without a liner, which could be provided) results in a metal body 270 of a contact structure 200. Where silicon nitride layer 112 constitutes an intrinsically stressed liner below ILD layer 108, metal body 170, 270 and dielectric spacer 130, 230 extend through the intrinsically stressed liner.

Returning to FIGS. 5 and 6, a contact structure 100, 200, respectively, formed according the embodiments described above may include a metal body 170, 270 surrounded by dielectric spacer 130, 230 and positioned within ILD layer 108. Metal body 170, 270 is electrically coupled to silicide region 122 below a lowermost portion 172, 272 of metal body 170, 270. As shown in FIG. 5 only, diffusion barrier liner 152 may be provided between metal body 170 and dielectric spacer 130. Dielectric spacer 130, 230 contacts silicide region 122 about metal body 170, 270, but does not prevent electrical connectivity. As shown in FIG. 6, in one embodiment, contact structure 200 may include an outer surface 218 that is substantially frusto-conical. Dielectric spacer 130, 230 substantially fills throat portion 116 (FIG. 3) of contact opening 114 in ILD layer 108 near an upper part of ILD layer 108.

The method as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The foregoing description of various aspects of the disclosure has been presented for purposes of illustration and description. It is not intended to be exhaustive or to limit the disclosure to the precise form disclosed, and obviously, many modifications and variations are possible. Such modifications and variations that may be apparent to a person skilled in the art are intended to be included within the scope of the disclosure as defined by the accompanying claims.

What is claimed is:

1. A contact structure comprising:
a metal body surrounded by a dielectric spacer, the metal body and the dielectric spacer positioned within an interlevel dielectric layer,
wherein the metal body is electrically coupled to a silicide region below a lowermost portion of the metal body.

2. The contact structure of claim 1, further comprising a refractory metal liner between the metal body and the dielectric spacer.

3. The contact structure of claim 1, wherein the dielectric spacer contacts the silicide region.

4. The contact structure of claim 1, further comprising an intrinsically stressed liner below the interlevel dielectric layer, wherein the metal body and the spacer extend through the intrinsically stressed liner.

5. The contact structure of claim 1, wherein the dielectric spacer includes a dielectric material having a dielectric constant less than approximately 2.9.

6. The contact structure of claim 1, wherein an outer surface of the dielectric spacer is substantially frusto-conical.

7. The contact structure of claim 1, wherein the dielectric spacer substantially fills a throat portion of a contact opening in the interlevel dielectric layer near an upper part of the interlevel dielectric layer.

8. A method comprising:
providing an interlevel dielectric layer having a contact opening therein, the contact opening exposing a silicide region at a lower portion of the contact opening;
forming a dielectric spacer within the contact opening;
performing an anisotropic reactive ion etch to remove the dielectric spacer at the lower portion of the contact opening and expose the silicide region; and
filling the contact opening with a metal.

9. The method of claim 8, wherein the contact opening includes a throat portion in the interlevel dielectric layer near an upper part of the interlevel dielectric layer.

10. The method of claim 8, further comprising forming a diffusion barrier liner before the filling.

11. The method of claim 8, further comprising:
performing an argon sputtering after the providing such that an outer surface of the contact opening is substantially frusto-conical;
wherein the dielectric spacer forming includes non-conformally depositing a dielectric such that an upper portion of the dielectric spacer is thicker than a lower portion of the dielectric spacer; and
wherein the anisotropic etch performing creates a substantially straight wall in the contact opening through the dielectric spacer.
